(19) United States
(12) Patent Application Publication
(10) Pub. No.: US 2026/0099091 A1
(43) Pub. Date: Apr. 9, 2026

(54) RETICLE POD HAVING TRANSPARENT WINDOW AND MANUFACTURING METHOD THEREOF

(71) Applicant: Gudeng Precision Industrial Co., LTD, New Taipei City (TW)

(72) Inventors: MING-CHIEN CHIU, New Taipei City (TW); JUI-YING TSAI, New Taipei City (TW); HSIN-MIN HSUEH, New Taipei City (TW); CHIA-HO CHUANG, New Taipei City (TW); CHOU-WEI WU, New Taipei City (TW)

(21) Appl. No.: 19/341,105

(22) Filed: Sep. 26, 2025

Related U.S. Application Data
(60) Provisional application No. 63/705,072, filed on Oct. 9, 2024.

(51) Int. Cl. G03F 1/66

(52) U.S. Cl. CPC G03F 1/66

(57) ABSTRACT

A reticle pod having a transparent window and a manufacturing method thereof, in which, the reticle pod includes a first housing, a second housing, a transparent window member, and a thermoplastic sealing material. The first housing is configured to mate with the second housing and the two define an accommodation space for receiving a reticle. The first housing includes a window formed therethrough for exposing the reticle. The transparent window member is disposed at the window to allow a light to pass through and reach the reticle. The thermoplastic sealing material is disposed between the first housing and the transparent window member and surrounds the transparent window member, thereby forming an airtight seal between the transparent window member and the first housing.

### RELATED APPLICATIONS

This application claims priority to U.S. Provisional Patent Application No. U.S. 63/705,072, by CHIU, et al., titled “RETICLE POD HAVING TRANSPARENT WINDOW,” filed on Oct. 9, 2024, which is hereby incorporated by reference in their entirety.

### BACKGROUND OF THE INVENTION

### Technical Field

The present invention relates to a reticle pod. More particularly, the present invention relates to a reticle pod having transparent window and manufacturing method thereof.

### Description of Related Art

Along with the advancement in technology, modern electronic devices are developed toward features such as light weight, small size, high operating frequency, and high energy efficiency. Such features require that the semiconductor components in the electronic devices are manufactured in a more compact and complicated manner. According to current semiconductor manufacturing techniques, a circuit pattern of a semiconductor component is transferred to a wafer surface by a photolithography process, which uses a reticle having a specific defined pattern. Modern photolithography process techniques implement deep ultraviolet (DUV) light, or even extreme ultraviolet (EUV) light having a very short wavelength, to achieve shorter pitches and line widths.

However, during the manufacturing process, any particles, residues, or contaminants adhering to a surface of the reticle may seriously affect the quality of the photolithography process. Therefore, a reticle pod is used to accommodate and transport the reticle. The reticle pod provides a clean and sealed internal space for accommodating the reticle. In the semiconductor process, certain mechanisms and methods are known to maintain the cleanliness and airtightness of the internal space of the reticle pod. However, when the reticle is to be accessed and used for the photolithography process, the reticle pod still needs to be opened. After the pattern on the reticle is transferred to a desired wafer, the reticle is re-placed into the reticle pod. The process of repeatedly opening and closing the reticle pod significantly increases the chances for particles or other contaminants to adhere to the surface of the reticle. Even with a purging operation or other proper cleaning operations, the problem of contaminant adhesion may not be avoided. As the photolithography process technology becomes increasingly complex and expensive, the requirements for protecting the reticle and maintaining its cleanliness during the process have become increasingly strict, which further highlights the problem of particles or contaminants adhering to the reticle.

The industry has proposed a reticle pod having at least one transparent window. The reticle remains within the reticle pod during optical inspection of the reticle surface or during the step of transferring the circuit pattern to a wafer. Therefore, the process of repeated opening and closing the reticle pod can be eliminated, thereby reducing the opportunities for particles or other contaminants to adhere onto the surface of the reticle.

However, a known assembly method for such a reticle pod includes the steps of assembling a window member with a frame and a gasket. First, the gasket is placed between the window member and a housing of the reticle pod. Then the frame is placed around the periphery of the window member. Screws are then used to fasten the frame to the housing of the reticle pod, and hence the gasket provides a sealing effect between the components. With this type of assembling method, because the gasket is pre-formed, gaps may easily form between the gasket and the housing of the reticle pod. Such gaps cannot be effectively cleaned, and moisture or particles may easily enter and remain within the gaps. In addition, a known material of the window member is glass, its surface is susceptible to charge accumulation due to friction or other effects, which may generate static electricity. Particles may easily adhere to the surface of the window member due to the static electricity. When particles adhere to the surface of the window member due to static electricity, they are often difficult to effectively remove. The adhered particles have a negative effect on the light passing through the window member, thereby causing distortion or deformation of the circuit pattern and lowering the quality of the photolithography process. This phenomenon may also cause an error during inspection of the reticle surface by an inspection device. Furthermore, in the assembly method using the gasket, the gasket material may also release volatile organic compounds (VOCs), which can contaminate the internal space of the reticle pod and have negative effect on the cleanliness.

### SUMMARY

In view of the above-mentioned problems, the present invention is to provide a reticle pod having a transparent window and a manufacturing method thereof, in which a transparent window member is airtightly sealed to a housing of the reticle pod by using a thermoplastic sealing material. The use of the thermoplastic sealing material avoids issues caused by the gaps in known assembly method and prevents the release of volatile organic compounds. Thus, the problems resulting from moisture or particles entering and remaining within the gap can be effectively prevented. The reticle pod therefore provides improved airtightness.

According to one aspect of the invention, a reticle pod having a transparent window is provided. The reticle pod includes: a first housing and a second housing configured to mate with each other and define an accommodating space therebetween for receiving a reticle, the first housing having a window formed therethrough for exposing the reticle; a transparent window member disposed at the window for allowing a light to pass through and reach the reticle; and a thermoplastic sealing material disposed between the first housing and the transparent window member and surrounding the transparent window member, thereby forming an airtight seal between the transparent window member and the first housing.

In one embodiment, the first housing has a flange and an inner sidewall continuously surrounding the window, and the flange protrudes from the inner sidewall for supporting the transparent window member.

In another embodiment, the thermoplastic sealing material is disposed between the inner sidewall and the transparent window member and between the flange and the transparent window member.

In yet another embodiment, the transparent window member has an inner surface and an outer surface opposite the inner surface, and the thermoplastic sealing material covers a periphery of the inner surface and the outer surface.

In a further embodiment, the transparent window member includes a quartz substrate having an inner surface and an opposite outer surface, and an anti-reflective layer and/or an anti-static layer is formed on at least one of the inner surface and the outer surface.

In another embodiment, the anti-reflective layer includes Titanium dioxide (TiO2), and the anti-static layer includes Indium Tin Oxide (ITO).

In yet another embodiment, the transparent window member includes a quartz substrate having an inner surface and an opposite outer surface, and an anti-reflective and anti-static composite material layer is formed on at least one of the inner surface and the outer surface.

In a further embodiment, the composite material layer includes TiO₂ and ITO.

In another embodiment, the transparent window member includes a quartz substrate having an inner surface and an opposite outer surface, and an anti-static layer or an anti-reflective and anti-static composite material layer is formed on at least one of the inner surface and the outer surface, and a surface resistance of the transparent window member is 10⁴≤Ω≤10⁹.

According to another aspect of the invention, a manufacturing method of a reticle pod having a transparent window is provided. The manufacturing method includes the steps of: providing a first housing having a window formed therethrough, the first housing being configured to mate with a second housing to define an accommodating space therebetween for receiving a reticle; providing a thermoplastic sealing material at the window such that the thermoplastic sealing material is arranged along an inner sidewall surrounding the window; and, disposing a transparent window member at the window such that the thermoplastic sealing material is disposed between the first housing and the transparent window member and surrounds the transparent window member, thereby forming an airtight seal between the transparent window member and the first housing.

According to the disclosure of the embodiments of the invention, the reticle pod having the transparent window and the manufacturing method thereof are provided. The thermoplastic sealing material is disposed surrounding the transparent window member and located between the housing of the reticle pod and the transparent window member, so as to airtightly seal the transparent window member to the housing. By this configuration, problems of moisture and particle residues caused by poor cleaning of the gap in known reticle pods can be avoided, and the reticle pod of the present embodiments has the advantage of improved airtightness. In addition, by using the thermoplastic sealing material, the problems associated with conventional use of pre-formed gaskets, such as assembly gap and the release of volatile organic compounds, can also be prevented.

### BRIEF DESCRIPTION OF DRAWINGS

The invention can be more fully understood by reading the following detailed description of the embodiment, with reference made to the accompanying drawings as follows:

FIG. 1 is an exploded diagram of a reticle pod according to one embodiment of the invention.

FIG. 2 is a three-dimensional diagram of the reticle pod of FIG. 2 after assembled.

FIG. 3 is a cross-sectional diagram of the reticle pod of FIG. 2 taken along line A-A′.

FIG. 4a is a schematic diagram of one embodiment of the configuration of the thermoplastic sealing material.

FIG. 4b is a schematic diagram of another embodiment of the configuration of the thermoplastic sealing material.

FIG. 4c is a schematic diagram of a further embodiment of the configuration of the thermoplastic sealing material.

FIG. 5 is a schematic diagram showing a side of the transparent window member according to one embodiment of the invention.

FIG. 6 is a schematic diagram showing a side of the transparent window member according to another embodiment of the invention.

FIG. 7 is a schematic diagram showing a side of the transparent window member according to a further embodiment of the invention.

FIG. 8 is a schematic diagram showing a side of the transparent window member according to yet another embodiment of the invention.

FIG. 9 is a transmittance curve diagram of light passing through the transparent window member according to one embodiment of the invention.

FIG. 10 is a transmittance curve diagram of light passing through the transparent window member according to another embodiment of the invention.

FIG. 11 is a flow chart of a manufacturing method of the reticle pod having transparent window according to one embodiment of the invention.

FIG. 12 is a flow chart of a manufacturing method of the reticle pod having transparent window according to another embodiment of the invention.

### DETAILED DESCRIPTION

The embodiments of the present invention provide a reticle pod having a transparent window and a manufacturing method thereof. A thermoplastic sealing material is disposed surrounding the transparent window member and disposed between a first housing of the reticle pod and the transparent window member, so as to airtightly seal the transparent window member to the first housing. The issues relating to moisture and particle residues in the assembly gap in known assembly method can be prevented. By using the thermoplastic sealing material, the problems associated with conventional use of pre-formed gaskets, such as forming assembly gaps and releasing volatile organic compounds, can also be prevented.

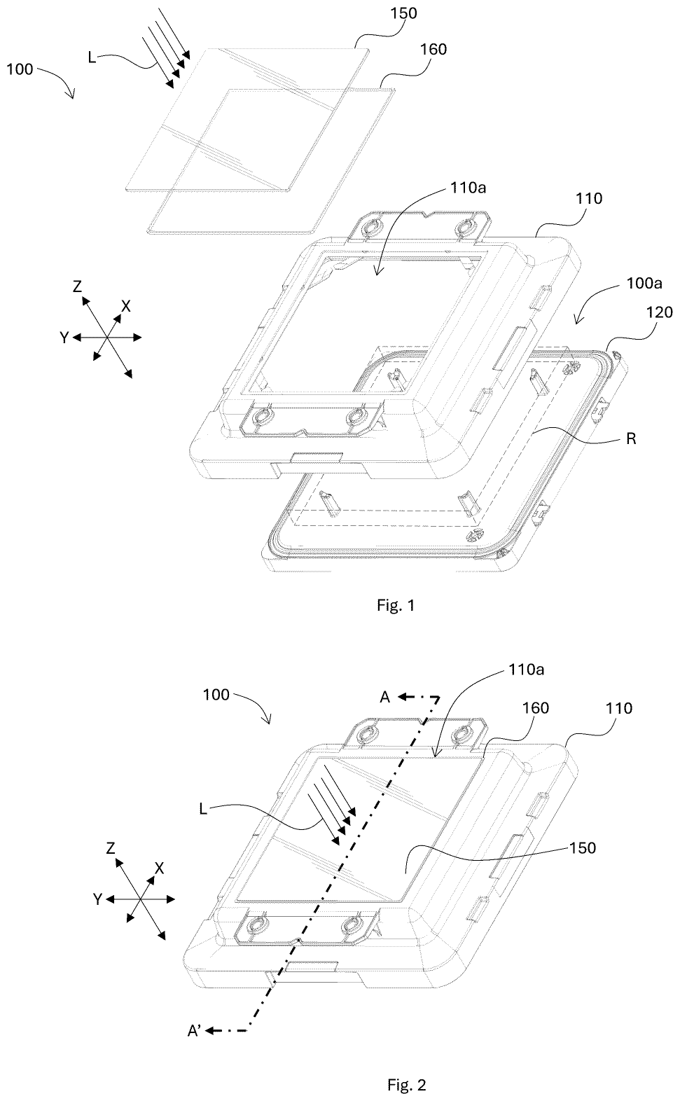

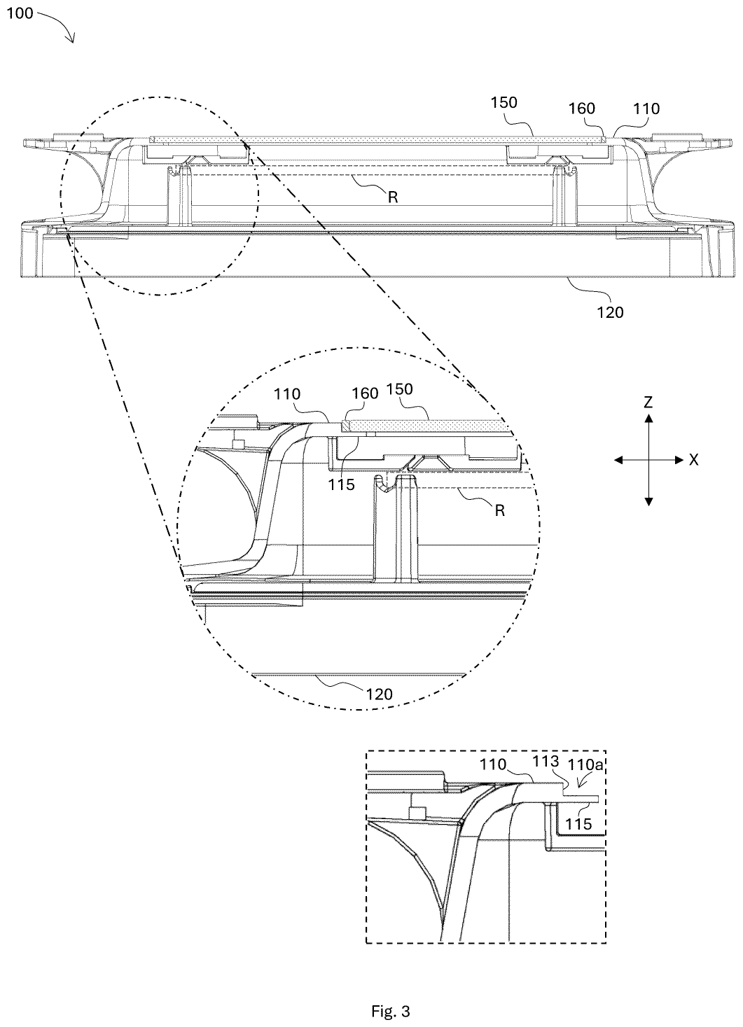

Please refer to FIG. 1 to FIG. 3 at the same time. FIG. 1 is an exploded diagram of a reticle pod according to one embodiment of the invention. FIG. 2 is a three-dimensional diagram of the reticle pod of FIG. 2 after assembled. FIG. 3 is a cross-sectional diagram of the reticle pod of FIG. 2 taken along line A-A′.

While the present invention has been disclosed above through a number of embodiments, those embodiments are not intended to be restrictive of the scope of the invention. A person who is skilled in the art will be able to make various changes or modifications to the disclosed embodiments without departing from the spirit or scope of the invention. The scope of the patent protection sought by the applicant is defined by the appended claims.

The reticle pod 100 having the transparent window according to the present embodiment includes a first housing 110, a second housing 120, a transparent window member 150, and a thermoplastic sealing material 160. The first housing 110 and the second housing 120 are configured to mate with each other and define an accommodating space 100a therebetween for receiving a reticle R. The first housing 110 has a window 110a formed therethrough for exposing the reticle R. The transparent window member 150 is disposed at the window 110a for allowing a light L to pass through and reach the reticle R. The thermoplastic sealing material 160 is disposed between the first housing 110 and the transparent window member 150 and surrounding the transparent window member 150, thereby forming an airtight seal between the transparent window member 150 and the first housing 110. In the reticle pod 100, the thermoplastic sealing material 160 is configured to surround the transparent window member 150 and sandwiched between the first housing 110 and the transparent window member 150, thereby airtightly sealing the transparent window member 150 to the first housing 110. The assembly gaps in known assembly method can be eliminated, thus preventing the issues relating to moisture and particle residues in the assembly gaps. Further, by using the thermoplastic sealing material 160 to seal the transparent window member 150, the problems associated with releasing volatile organic compounds from conventional gasket can be prevented.

As shown in FIG. 3, in the present embodiment, the first housing 110 has a flange 115 and an inner sidewall 113 continuously surrounding the window 110a, and the flange 115 protrudes from the inner sidewall 113 for supporting the transparent window member 150. The window 110a is surrounded by the continuously surrounding inner sidewall 113; in other words, the inner sidewall 113 constitutes the windows 110a. On the horizontal plane (i.e., the plane formed by directions X and Y in FIG. 1), the cross-sectional area of the window 110a is marginally larger than that of the transparent window member 150. As a result, the transparent window member 150 can be place into the window 110a and then airtightly sealed by the thermoplastic sealing material 160.

Now the detailed description directs to the embodiments of the configuration of the thermoplastic sealing material 160.

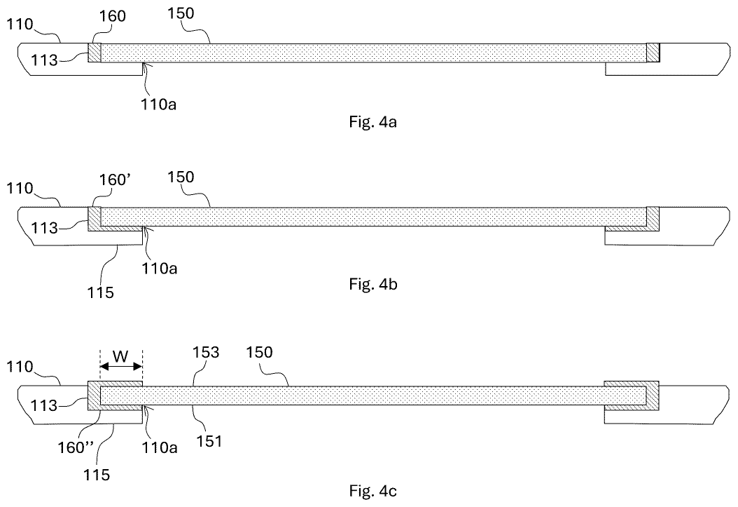

Please refer to FIG. 4a to FIG. 4c. FIG. 4a is a schematic diagram of one embodiment of the configuration of the thermoplastic sealing material. FIG. 4b is a schematic diagram of another embodiment of the configuration of the thermoplastic sealing material. FIG. 4c is a schematic diagram of a further embodiment of the configuration of the thermoplastic sealing material.

In the embodiment shown in FIG. 4a, the thermoplastic sealing material 160 is disposed between the inner sidewall 113 and the transparent window member 150, thereby sealing and fixing the transparent window member 150 to the window 150a. As a result, the transparent window member 150 is airtightly sealed and disposed at the window 110a.

In the embodiment shown in FIG. 4b, the thermoplastic sealing material 160′ is disposed between the inner sidewall 113 and the transparent window member 150 and between the flange 115 and the transparent window member 150. The flange 115 protrudes toward a center of the window 110a from the inner sidewall 113 by a distance, whereby forming an L-shape supporting structure. The thermoplastic sealing material 160′ is disposed at this location in a corresponding L-shape, and the transparent window member 150, in turn, is disposed on the thermoplastic sealing material 160′. The transparent window member 150 is therefore sealed and fixed to the window 150a. As a result, the transparent window member 150 is airtightly sealed and disposed at the window 110a.

In the embodiment shown in FIG. 4c, the transparent window member 150 has an inner surface 151 and an outer surface 153 opposite the inner surface 151. The thermoplastic sealing material 160″ covers a periphery W of the inner surface 151 and the outer surface 153. In this manner, the thermoplastic sealing material 160″ covers and fixes the transparent window member 150 from three sides, namely, a lower side (between the transparent window member 150), a lateral side (between the transparent window member 150 and the inner sidewall 113), and an upper side (on the outer surface 153 of the transparent window member 150), thereby achieving an enhanced fixing and airtight-sealing effect.

In the embodiments of the present invention, the thermoplastic sealing material 160, 160′ and 160″ may be formed at the window 110a of the first housing 110, for example, by a process in which thermoplastic material is melted through plastic over-molding, ultrasonic welding, laser welding, or the like. By such formation, moisture or particles remaining in the gaps, due to difficulties in cleaning the known assembled-type reticle pod, can be reduced. Furthermore, by using the thermoplastic sealing material 160, 160′ and 160″, the problem of volatile organic compounds being released from conventional gasket materials can be avoided, thereby maintaining the cleanliness inside the reticle pod 100.

The detailed description now elaborates the transparent window member 150.

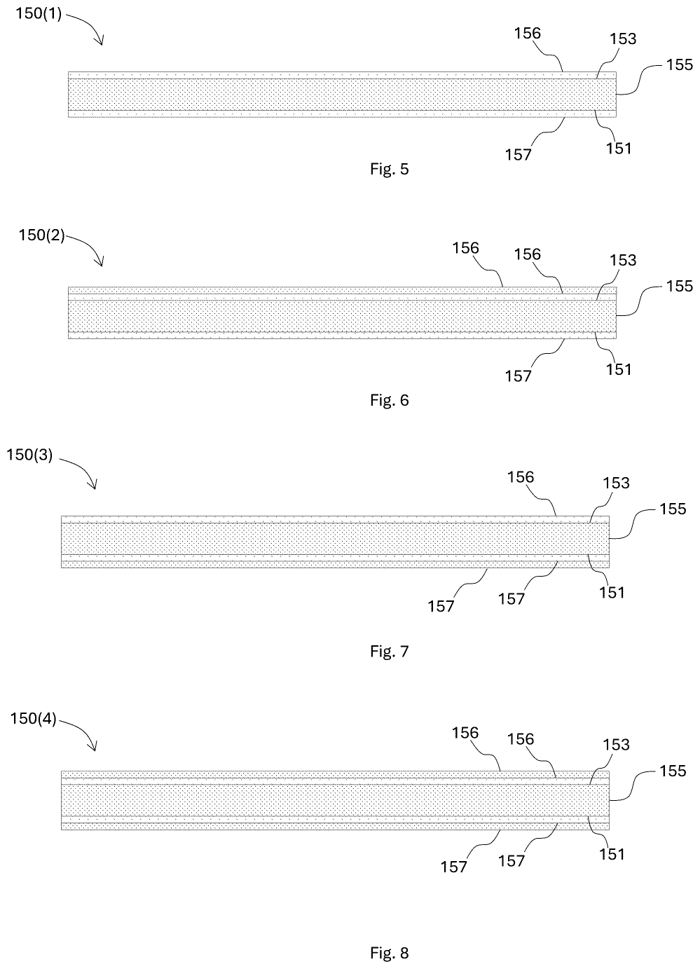

Please refer to FIG. 5, which is a schematic diagram showing a side of the transparent window member according to one embodiment of the invention. The transparent window member 150(1) includes a quartz substrate 155 having an inner surface 151 and an opposite outer surface 153, in which the outer surface 153 faces away from the second housing 120 (the second housing 120 is shown in FIGS. 1-3). In this embodiment, the outer surface 153 is the upward-facing surface (upward direction in the vertical direction Z of FIGS. 2 and 3). An anti-reflective layer and/or an anti-static layer is formed on the outer surface 153. In addition, another anti-reflective layer and/or anti-static layer is also formed on the inner surface 151. As shown in FIG. 5, in this embodiment, the outer surface 153 has one material coating layer 156 thereon, which can be the anti-reflective layer or the anti-static layer. Similarly, the inner surface 151 has one material coating layer 157 thereon, which may also be the anti-reflective layer or the anti-static layer. In practical applications, the anti-reflective layer may include, for example, titanium dioxide (TiO₂), and the anti-static layer may include, for example, indium tin oxide (ITO).

In a different embodiment, the material coating layer 156 on the outer surface 153 can be an anti-reflective and anti-static composite material layer, which includes TiO₂ and ITO at the same time. Similarly, the material coating layer 157 on the inner surface 151 can be an anti-reflective and anti-static composite material layer also including TiO₂ and ITO.

Please refer to FIG. 6, which is a schematic diagram showing a side of the transparent window member according to another embodiment of the invention. The transparent window member 150(2) includes a quartz substrate 155 having an inner surface 151 and an opposite outer surface 153, in which the outer surface 153 faces away from the second housing 120 and is the upward-facing surface. Two material coating layers 156 are formed on the outer surface 153, which respectively are an anti-reflective layer and an anti-static layer. One material coating layer 157 is formed on the inner surface 151, which is an anti-reflective layer or an anti-static layer. The anti-reflective layer may include, for example, TiO₂, and the anti-static layer may include, for example, ITO.

Please refer to FIG. 7, which is a schematic diagram showing a side of the transparent window member according to a further embodiment of the invention. The transparent window member 150(3) includes a quartz substrate 155 having an inner surface 151 and an opposite outer surface 153, in which the outer surface 153 faces away from the second housing 120 and is the upward-facing surface. One material coating layer 156 is formed on the outer surface 153, which is an anti-reflective layer or an anti-static layer. Two material coating layers 157 are formed on the inner surface 151, which respectively are an anti-reflective layer and an anti-static layer. The anti-reflective layer may include, for example, TiO₂, and the anti-static layer may include, for example, ITO.

Please refer to FIG. 8, which is a schematic diagram showing a side of the transparent window member according to yet another embodiment of the invention. The transparent window member 150(4) includes a quartz substrate 155 having an inner surface 151 and an opposite outer surface 153, in which the outer surface 153 faces away from the second housing 120 and is the upward-facing surface. Two material coating layers 156 are formed on the outer surface 153, which respectively are an anti-reflective layer and an anti-static layer. Similarly, two material coating layers 157 are formed on the inner surface 151, which respectively are an anti-reflective layer and an anti-static layer. The anti-reflective layer may include, for example, TiO₂, and the anti-static layer may include, for example, ITO.

According to the embodiments of the invention, the transparent window member 150 is disposed at the window 110a of the first housing 110, allowing the light L to pass through and reach the reticle R received in the accommodating space 100a. The anti-reflective layer formed on the transparent window member 150 is used for reducing a surface reflection and increasing the transmission rate of the light L. The anti-static layer formed on the transparent window member 150 is used for preventing the particles from being adhered to the transparent window member 150, maintaining the cleanliness.

The transmittances of the light L with respect to different wavelengths are measured in laboratory tests and are elaborated as follows.

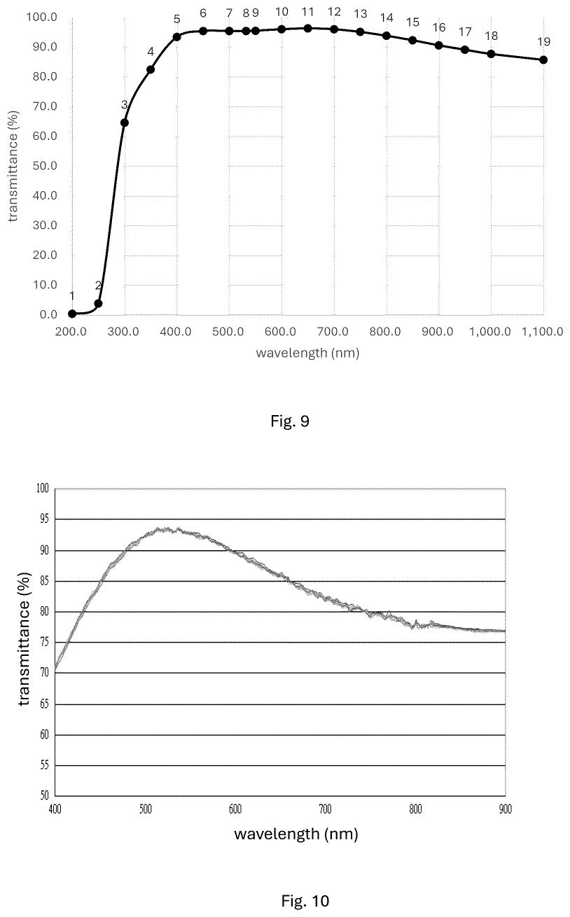

Please refer to FIG. 9, which is a transmittance curve diagram of light passing through the transparent window member according to one embodiment of the invention. By way of example, the transparent window member 150(1) of FIG. 5 has its inner surface 151 and outer surface 153 respectively formed with the material coating layers 156 and 157. During the laboratory tests, the anti-reflective layer is formed on the outer surface 153 of the transparent window member 150(1), and the anti-static layer is formed on the inner surface 151. Accordingly, the material coating layer 156 on the outer surface 153 is the anti-reflective layer, and the material coating layer 157 on the inner surface 151 is the anti-static layer. The transparent window member 150(1) is irradiated with light L having wavelengths ranging from 200 nm to 1100 nm, and the transmittances of the light L at different wavelengths are measured respectively. The data from the laboratory tests are summarized in Table 1 below.

TABLE 1

| | wavelength(nm) | | | | | | | | | |
|---|---|---|---|---|---|---|---|---|---|---|
| | 200.0 | 250.0 | 300.0 | 350.0 | 400.0 | 450.0 | 500.0 | 532.0 | 550.0 | 600.0 |
| transmittance(%) | 0.40 | 3.90 | 64.60 | 82.50 | 93.40 | 95.40 | 95.40 | 95.40 | 95.50 | 96.00 |

wavelength (nm)

| | 650.0 | 700.0 | 750.0 | 800.0 | 850.0 | 900.0 | 950.0 | 1000.0 | 1100.0 |
|---|---|---|---|---|---|---|---|---|---|
| Transmittance(%) | 96.30 | 96.00 | 95.10 | 93.80 | 92.30 | 90.60 | 89.10 | 87.70 | 85.70 |

According to Table 1 and FIG. 9, within the wavelength range of approximately 400 nm to 900 nm, the light L exhibits a relatively high transmittance. In this range, the transmittance of the light L exceeds 90%, with the maximum transmittance reaching 96.30% when the wavelength of light L is 650.0 nm.

Next, please refer to FIG. 10, which is a transmittance curve diagram of light passing through the transparent window member according to another embodiment of the invention. By way of example, the transparent window member 150(1) of FIG. 5 has its inner surface 151 and outer surface respectively formed with the material coating layers 156 and 157. Here, the two material coating layers 156 and 157 are anti-reflective and anti-static composite material layers. The transparent window member 150(1) is irradiated with light L having wavelengths ranging from 400 nm to 900 nm, and the transmittances of the light L at different wavelengths are measured respectively. As shown in FIG. 10, the light L exhibits a relatively high transmittance in the approximately wavelength range of 450 nm to 600 nm, which reaches 95%. In a preferable embodiment, a transmittance of 95.4% is achieved when the wavelength of light L is 532 nm.

Regarding the anti-static effect of the anti-static layer, according to the results of laboratory experiments, when ITO is used as the anti-static layer, its conductive properties allow the surface resistance of the transparent window members 150(1), 150(2), 150(3), or 150(4) to be controlled within the range of 10⁴≤Ω≤10⁹. This effectively prevents the adhesion of particles to the transparent window members 150(1), 150(2), 150(3), or 150(4).

According to the embodiments of the invention, the reticle pod having transparent window includes the thermoplastic sealing material disposed between the first housing of the reticle pod and the transparent window member and surrounding the transparent window member, thereby providing airtight seal between the transparent window member and the first housing. The embodiments of the invention prevent the problems resulting from moisture or particles entering and remaining within the assembly gap, and avoid the drawbacks relating to the release of volatile organic compounds. As a result, the reticle pod exhibits improved airtightness. Furthermore, by forming anti-reflective layer and/or anti-static layer on the transparent window member, the transmittance of the light at specific wavelength is enhanced. The surface static electricity can also be inhibited, thereby reducing particle adhesion and thus increasing the readability of the reticle R.

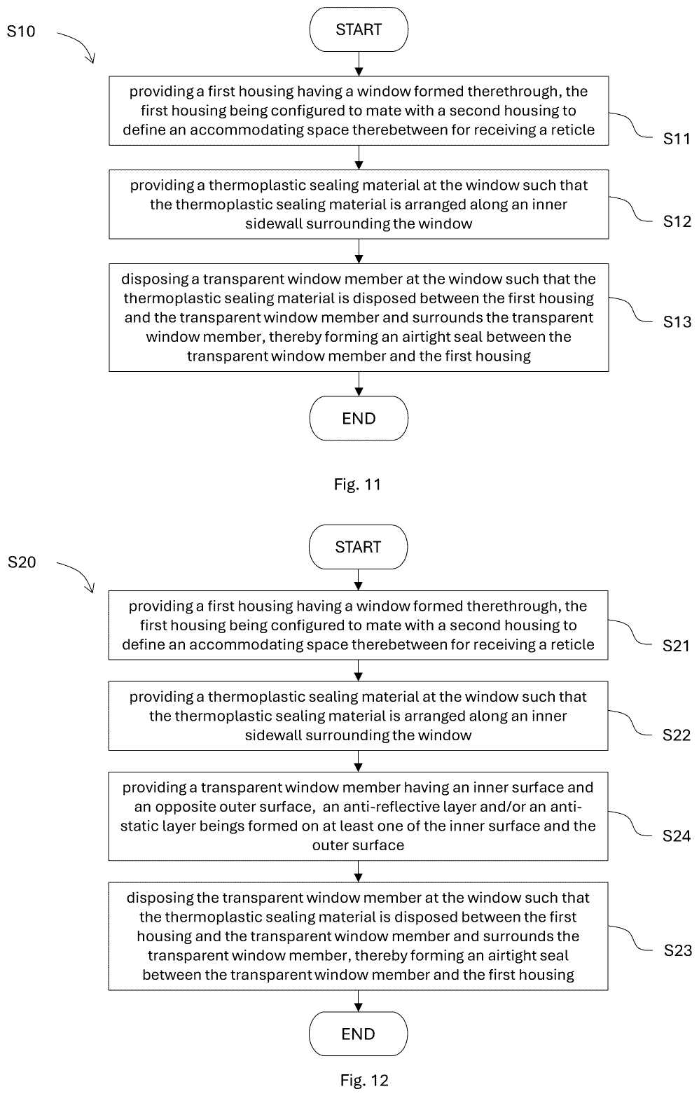

The detailed description is now directed to a manufacturing method of the reticle pod having transparent window. Please refer to FIG. 11, which is a flow chart of a manufacturing method of the reticle pod having transparent window according to one embodiment of the invention. The manufacturing method S10 of the present embodiment is used to manufacture the reticle pod 100 in the aforementioned embodiments, for example. Please also refer to FIG. 1 to FIG. 4c. In the description of the present embodiment, the same elements in different embodiments are assigned the same element numbers for consistency and to clearly illustrate the features of the embodiments. The manufacturing method S10 of the present embodiment includes the following steps.

First, in step S11, the first housing is provided. The first housing 110 has the window 110a formed therethrough. The first housing 110 is configured to mate with the second housing 120 to define the accommodating space 100a therebetween for receiving the reticle R.

Then, in step S12, the thermoplastic sealing material 160 is provided at the window 110a such that the thermoplastic sealing material 160 is arranged along the inner sidewall 113 surrounding the window 110a.

Further, in step S13, the transparent window member 150 is disposed at the window 110a such that the thermoplastic sealing material 160 is disposed between the first housing 110 and the transparent window member 150 and surrounds the transparent window member 150, thereby forming airtight seal between the transparent window member 150 and the first housing 110.

According to the manufacturing method S10 of the present embodiment, the thermoplastic sealing material 160 is configured to surround the transparent window member 150 and is disposed between the first housing 110 and the transparent window member 150. As a result, the transparent window member 150 can be airtightly sealed to the first housing 110, thereby preventing problems associated with moisture and particles remaining in the assembly gaps. Furthermore, the use of the thermoplastic sealing material 160 also eliminates issues related to the release of volatile organic compounds. Accordingly, the reticle pod 100 exhibits improved airtightness.

Please refer to FIG. 12, which is a flow chart of a manufacturing method of the reticle pod having transparent window according to another embodiment of the invention. The manufacturing method S20 of the present embodiment is used to manufacture the reticle pod 100 in the aforementioned embodiments, for example. Please also refer to FIG. 1 to FIG. 4c. In the description of the present embodiment, the same elements are assigned the same element numbers. The manufacturing method S20 of the present embodiment includes the following steps.

In step S21, the first housing 110 is provide. The first housing 110 has the window 110a formed therethrough. The first housing 110 is configured to mate with the second housing 120 to define the accommodating space 100a therebetween for receiving the reticle R. Next in step S22, the thermoplastic sealing material 160 is provided at the window 110a such that the thermoplastic sealing material 160 is arranged along the inner sidewall 113 surrounding the window 110a. Then in step S23, the transparent window member 150 is disposed at the window 110a such that the thermoplastic sealing material 160 is disposed between the first housing 110 and the transparent window member 150 and surrounds the transparent window member 150, thereby forming airtight seal between the transparent window member 150 and the first housing 110.

The manufacturing method S20 of the present embodiment further includes step S24, in which the transparent window member 150, having the inner surface 151 and the opposite outer surface 153, is provided. In step S24, the anti-reflective layer and/or the anti-static layer is formed on at least one of the inner surface 151 and the outer surface 153. The technical features and contents of the one or more material coating layers 156 and 157 on the inner surface 151 and/or the outer surface 153 are the same as those described in the embodiments of FIG. 5 to FIG. 10, and are not repeated here.

In a different embodiment, the transparent window member 150 provided in step S24 has at least one of its inner surface 151 and the outer surface 153 formed with a single anti-reflective and anti-static composite material layer.

In the present embodiment, step S21 and step S24 are independent and may be performed in any order. Either step can be performed before the other, or they may be performed simultaneously. More specifically, in one embodiment, the manufacturing method S20 may be performed in the following order: step S21, step S22, step S24, and then step S23. In another embodiment, the manufacturing method S20 may be performed in the order: step S21, step S24, step S22, and then S23. In a further embodiment, the manufacturing method S20 may be performed in the order: step S24, step S21, step S22, and then S23.

Based on the above, in the reticle pod having transparent window and the manufacturing method thereof according to the embodiments of the invention, the thermoplastic sealing material is disposed between the housing of the reticle pod and the transparent window member and surrounds the transparent window member. The transparent window member is thereby airtightly sealed to the housing. The embodiments prevent problems associated with moisture and particles remaining in the assembly gaps of known assembled-type reticle pods, thereby providing improved airtightness. Furthermore, by using the thermoplastic sealing material, the release of volatile organic compounds from conventional gasket materials can also be avoided.

Although the present invention has been disclosed with a number of embodiments as above, they are not intended to limit the present invention. Any person skilled in the art can make various modifications and refinements without departing from the spirit and scope of the present invention. Therefore, the protection scope of the present invention shall be defined by the scope of the appended claims.

What is claimed is:

1. A reticle pod having a transparent window, comprising:
a first housing and a second housing configured to mate with each other and define an accommodating space therebetween for receiving a reticle, the first housing having a window formed therethrough for exposing the reticle;
a transparent window member disposed at the window for allowing a light to pass through and reach the reticle; and
a thermoplastic sealing material disposed between the first housing and the transparent window member and surrounding the transparent window member, thereby forming an airtight seal between the transparent window member and the first housing.

2. The reticle pod according to claim 1, wherein the first housing has a flange and an inner sidewall continuously surrounding the window, and the flange protrudes from the inner sidewall for supporting the transparent window member.

3. The reticle pod according to claim 2, wherein the thermoplastic sealing material is disposed between the inner sidewall and the transparent window member and between the flange and the transparent window member.

4. The reticle pod according to claim 1, wherein the transparent window member has an inner surface and an outer surface opposite the inner surface, and the thermoplastic sealing material covers a periphery of the inner surface and the outer surface.

5. The reticle pod according to claim 1, wherein the transparent window member comprises a quartz substrate having an inner surface and an opposite outer surface, wherein an anti-reflective layer and/or an anti-static layer is formed on at least one of the inner surface and the outer surface.

6. The reticle pod according to claim 5, wherein the anti-reflective layer comprises Titanium dioxide (TiO₂), and the anti-static layer comprises Indium Tin Oxide (ITO).

7. The reticle pod according to claim 1, wherein the transparent window member comprises a quartz substrate having an inner surface and an opposite outer surface, wherein an anti-reflective and anti-static composite material layer is formed on at least one of the inner surface and the outer surface.

8. The reticle pod according to claim 7, wherein the composite material layer comprises TiO₂ and ITO.

9. The reticle pod according to claim 1, wherein the transparent window member comprises a quartz substrate having an inner surface and an opposite outer surface, wherein an anti-static layer or an anti-reflective and anti-static composite material layer is formed on at least one of the inner surface and the outer surface, and a surface resistance of the transparent window member is 10⁴≤Ω≤10⁹.

10. A manufacturing method of a reticle pod having a transparent window, comprising:
providing a first housing having a window formed therethrough, the first housing being configured to mate with a second housing to define an accommodating space therebetween for receiving a reticle;
providing a thermoplastic sealing material at the window such that the thermoplastic sealing material is arranged along an inner sidewall surrounding the window; and
disposing a transparent window member at the window such that the thermoplastic sealing material is disposed between the first housing and the transparent window member and surrounds the transparent window member, thereby forming an airtight seal between the transparent window member and the first housing.
